(19) United States
(12) Patent Application Publication
(10) Pub. No.: US 2026/0247793 A1
(43) Pub. Date: Aug. 20, 2026

(54) ELECTROLUMINESCENT DEVICE, METHOD FOR MANUFACTURING SAME, AND DISPLAY DEVICE

(71) Applicant: Sharp Display Technology Corporation, Kameyama City, Mie (JP)

(72) Inventors: Katsuhiko KISHIMOTO, Kameyama City, Mie (JP); Masanobu MIZUSAKI, Kameyama City, Mie (JP)

(21) Appl. No.: 19/162,205

(22) PCT Filed: Mar. 6, 2023
(86) PCT No.: PCT/JP2023/008271

§ 371 Date: Sep. 4, 2025

(51) Int. Cl. H10K 50/19; H10K 50/11

(52) U.S. Cl. CPC H10K 50/19; H10K 50/11

(57) ABSTRACT

An electroluminescent device (13) includes electroluminescent layers of a first color to an n-th color (n is 2 or more) that emit light of different colors in a direction intersecting a layering direction, and includes a first electroluminescent layer (34) on an anode electrode layer side and a second electroluminescent layer (53) on a cathode electrode layer side with a charge generation layer (40) interposed therebetween in the layering direction. The ratio of the thickness of the first electroluminescent layer (34) to the thickness of the second electroluminescent layer (53) is larger than 1/15 and smaller than 4/15.

### TECHNICAL FIELD

The disclosure relates to an electroluminescent device, a method for manufacturing the same, and a display device.

### BACKGROUND ART

Mass production of a display equipped with an organic-EL element (also referred to as “organic light emitting diode” or “OLED”) is started in earnest with a thin display for a highend model of a smartphone or a TV. The display of an organic-EL element is now in widespread use to the extent that it can be said to have become a centerpiece of a thin display as a replacement for a liquid crystal display.

A thin film layered type organic-EL element using an aluminum quinolinol complex (Alq₃) in an electron transport electroluminescent layer is known. However, for further improvement of the luminous efficiency in the organic-EL element, development is advanced in the order of the following (1) to (3).
(1) A host/guest system material in which a guest compound as a dopant is added to a host compound is used as a material for an electroluminescent layer, a carrier (electron/hole) transport layer, or a carrier (electron/hole) injection layer of the organic-EL element.
(2) As the guest compound (dopant) for the electroluminescent layer, a fluorescent light emitting material, or a fluorescent light emitting material and a phosphorescent light emitting material are used.
(3) An improved guest compound such as a thermally activated delayed fluorescence (TADF) material or a hyperfluorescence material is used as the dopant in the electroluminescent layer.

In addition, from the viewpoint of improving a current efficiency and an element lifetime in the organic-EL element, the following (4) and (5) are further studied.
(4) The carrier transport layer or the carrier injection layer is devised to improve a carrier balance.
(5) A tandem structure is employed for the element structure of the light emitting element (see, for example, PTLs 1 and 2).

### CITATION LIST

### Patent Literature

PTL 1: JP 2007-329054 A
PTL 2: WO 2010/113493

### SUMMARY

### Technical Problem

However, when light emitting layers of the respective colors of RGB are separately applied to enable full color display and a tandem structure is adopted, the advantage of adopting the tandem structure is not sufficiently exhibited in some cases.

An aspect of the disclosure is directed to providing a technique capable of sufficiently exhibiting the advantage of adopting the tandem structure in an electroluminescent device capable of full color display.

### Solution to Problem

An electroluminescent device according to one aspect of the disclosure includes: an anode electrode layer; a cathode electrode layer facing the anode electrode layer in a layering direction; a plurality of electroluminescent layers disposed between the anode electrode layer and the cathode electrode layer in the layering direction and in a direction intersecting the layering direction; and a charge generation layer disposed between two of the plurality of electroluminescent layers adjacent to each other in the layering direction, in which of the electroluminescent layers, the plurality of electroluminescent layers that emit light of a same color are disposed in the layering direction, a first color electroluminescent layer to an n-th color electroluminescent layer (n is an integer of 2 or more) that emit light of colors different from each other are disposed in the direction intersecting the layering direction, and in at least one set of sets of the electroluminescent layers, each of the sets being two of the plurality of electroluminescent layers adjacent to each other with the charge generation layer interposed therebetween in the layering direction, a ratio of a thickness of the electroluminescent layer on an anode electrode layer side in the layering direction to a thickness of the electroluminescent layer on a cathode electrode layer side in the layering direction is larger than 1/15 and smaller than 4/15.

A display device according to an aspect of the disclosure includes the above-described electroluminescent device.

A method for manufacturing an electroluminescent device according to an aspect of the disclosure is a method for manufacturing the above-described electroluminescent device, the method including alternately forming each of the plurality of electroluminescent layers and the charge generation layer on the anode electrode layer or the cathode electrode layer in the layering direction, in which the plurality of electroluminescent layers are formed by a vapor deposition method.

### Advantageous Effects of Disclosure

According to an aspect of the disclosure, it is possible to sufficiently exhibit the advantage of adopting the tandem structure in an electroluminescent device capable of full color display.

### BRIEF DESCRIPTION OF DRAWINGS

FIG. 1 is a plan view schematically illustrating a configuration of a display device according to a first embodiment of the disclosure.

FIG. 2 is a diagram schematically illustrating a layer configuration of the display device in FIG. 1.

FIG. 3 is a diagram schematically illustrating a layer configuration of an electroluminescent element in the layer configuration illustrated in FIG. 2.

FIG. 4 is a flowchart illustrating an example of a method for manufacturing the electroluminescent element illustrated in FIG. 3.

FIG. 5 is a diagram for explaining a light emission mechanism of the electroluminescent element of the electroluminescent device illustrated in FIG. 2.

FIG. 6 is a diagram for explaining a light emission mechanism of an electroluminescent element of an electroluminescent device according to a second embodiment of the disclosure.

### DESCRIPTION OF EMBODIMENTS

### Electroluminescent Element

An electroluminescent element according to an embodiment of the disclosure includes an anode electrode layer, a cathode electrode layer, an electroluminescent layer, and a charge generation layer. The electroluminescent element of the disclosure includes a plurality of electroluminescent layers layered in a layering direction. In at least one set of sets of the electroluminescent layers, each of the sets being two electroluminescent layers adjacent to each other with the charge generation layer interposed therebetween, the thickness of an electroluminescent layer on the cathode electrode layer side has a specific ratio relative to the thickness of an electroluminescent layer on the anode electrode layer side. The electroluminescent element of the disclosure may employ a known element configuration of a light emitting element within a range of including layers satisfying these conditions. Hereinafter, the layer configuration of the electroluminescent element of the disclosure will be described mainly by taking an OLED as an example. Note that in the disclosure, the “electroluminescent element” means an arrangement group of the electroluminescent layers and various carrier function layers in the layering direction. In the disclosure, the “electroluminescent device” means a group of a plurality of electroluminescent elements in a direction intersecting the layering direction.

### Anode Electrode Layer

The anode electrode layer is one electrode layer of a pair of electrode layers of an anode electrode and a cathode electrode, and is an electrode layer for supplying a hole to each layer constituting the electroluminescent element in the disclosure. The anode electrode layer has electrical conductivity. The anode electrode layer also has optical characteristics of, for example, reflecting part of visible light and transmitting the rest thereof. The anode electrode layer typically includes both an electrode material that reflects visible light and an electrode material that transmits visible light.

As a material of the anode electrode layer, a material having a relatively large work function (for example, a material having a work function of 4.5 eV or more) is suitably used from the viewpoint of enhancing a hole injection property. Examples of the electrode material having a large work function include Pt (5.65 eV), Ir (5.25 eV), Ni (5.2 eV), Au and Pd (5.15 eV), and indium tin oxide (In—Sn—O).

Examples of the electrode material that reflects visible light include metal materials such as Al, Mg, Li, Ag, Pd, and Cu, and alloys of these metal materials (for example, an APC (Ag—Pd—Cu) alloy).

Examples of the electrode material that transmits visible light include thin films formed of transparent metal oxides (for example, indium tin oxide (In—Sn—O), indium zinc oxide (In—Zn—O), indium gallium zinc oxide (In—Ga—Zn—O), and the like), thin films formed of metal materials such as Al, Mg, and Ag, and nanowires (NWs) formed of the metal materials.

Among the transparent metal oxides, In—Sn—O has a relatively high work function of 4.6 to 5.0 eV and is suitably used as the material of the anode electrode layer. Furthermore, for the anode electrode layer, a layered body (for example, In—Sn—O/Ag) in which In—Sn—O is formed on the surface of a metal material may be used for the purpose of improving electrical conductivity as an electrode layer or adding a function of reflecting visible light.

### Cathode Electrode Layer

The cathode electrode layer is the other electrode layer of the pair of electrode layers of the anode electrode and the cathode electrode, and is an electrode layer for supplying an electron to each layer constituting the electroluminescent element in the disclosure. The cathode electrode layer is disposed to face the anode electrode layer in the layering direction. The cathode electrode layer has, for example, electrical conductivity and transparency of visible light.

As a material of the cathode electrode layer, a material having a relatively small work function is suitably used from the viewpoint of, for example, enhancing an electron injection property. Examples of the electrode material constituting the cathode electrode layer include metal materials such as alkali metals, alkaline earth metals, and Al, alloys including these metals, and nanowires (for example, nanowires of Ag). Examples of the alloy include an alloy of Mg and Ag, and Al doped with a small amount of Li.

### Electroluminescent Layer

The electroluminescent layer is a layer that emits light of a predetermined color by application of an electrical field. The electroluminescent layer is usually composed of a light emitting material, but may have a layered structure of a plurality of function layers in which two or more function layers corresponding to two or more functions for electroluminescence in a known electroluminescent layer overlap, such as a layer that emits light immediately and a layer that emits light with delay, and the function of electroluminescence is expressed as a whole. In the disclosure, a plurality of electroluminescent layers are disposed between the anode electrode layer and the cathode electrode layer in the layering direction and in a direction intersecting the layering direction.

As the electroluminescent layer, a plurality of electroluminescent layers that emit light of a same color are disposed in the layering direction. The number of electroluminescent layers that emit light of the same color and overlap in the layering direction is preferably 3 or less, from the viewpoint of an increase in drive voltage, the viewpoint of a problem of a withstand voltage of a driver in response to the increase in drive voltage, and the viewpoint of maintaining flexibility (total thickness of the electroluminescent element).

In the disclosure, the thickness of the electroluminescent layer on the anode electrode layer side is significantly smaller than the thickness of the electroluminescent layer on the cathode electrode layer side, and the thickness of the electroluminescent layer on the cathode electrode layer side is significantly larger than the thickness of the electroluminescent layer on the anode electrode layer side. Thus, from the viewpoint of solving the problem of carrier balance in the charge generation layer described below with a smaller number of electroluminescent layers, the number of electroluminescent layers disposed in the layering direction is preferably 2. Note that the total number of electroluminescent layers disposed in the layering direction is preferably the same regardless of luminescent colors.

Here, the same color refers to colors of light in which, in a case where there are two or more light emission peak wavelengths, all the light emission peak wavelengths are within a range of ±5 nm from each other, and the maximum value of the full widths at half maximum of all the light emission peak wavelengths is 1.25 times or less the minimum value of the full widths at half maximum of the remaining light emission peak wavelengths. Basically, in a case where both a host material and a guest compound constituting the electroluminescent layer are the same material or similar materials having a same skeleton, the electroluminescent layer emits light of the same color. However, in a top emission structure described below, light emission peak wavelengths of colors may vary depending on a difference in microcavity structures of the colors. Thus, in the top emission structure, the same color refers to colors of light in which all light emission peak wavelengths are within a range of ±10 nm and the full width at half maximum satisfies the above range.

In addition, as the electroluminescent layer, a first color electroluminescent layer to an n-th color electroluminescent layer (n is an integer of 2 or more) that emit light of colors different from each other are disposed in a direction intersecting the layering direction. Here, the different colors refer to colors of light in a range not included in the same color described above. As a typical example of known electroluminescent layers of a plurality of colors for full color display, there are known three color light emitting layers of a red light emitting layer, a green light emitting layer, and a blue light emitting layer. In this manner, disposing the electroluminescent layers of a plurality of colors in the direction intersecting the layering direction may be referred to as “separately applying”. Note that it is preferable that the number of electroluminescent layers of each color in the layering direction is the same for all the luminescent colors. The electroluminescent layer in the disclosure will be described below mainly by taking the above three color light emitting layers as an example, but the disclosure is not limited thereto. Note that the electroluminescent layers of colors different from each other in the intersecting direction may be at a same position (height) or different positions (heights) (may be shifted) in the layering direction.

That is, in the disclosure, in a case where the electroluminescent device includes electroluminescent layers of three colors of red, green, and blue, electroluminescent elements of the respective colors are independently disposed in the direction intersecting the layering direction, for example, a direction orthogonal to the layering direction. In the layering direction, a red electroluminescent layer is disposed to overlap with a red electroluminescent layer, a green electroluminescent layer is disposed to overlap with a green electroluminescent layer, and a blue electroluminescent layer is disposed to overlap with a blue electroluminescent layer. Note that although an electroluminescent layer of a different color may be further layered in the layering direction, it is preferable that only a plurality of electroluminescent layers emitting light of the same color are disposed in the layering direction from the viewpoint of improving color purity. The fact that only the electroluminescent layers of the same color are layered in the layering direction is advantageous also from the viewpoint of more easily determining the thickness of the electroluminescent layer described below.

In an electroluminescent element in which three or more electroluminescent layers are disposed in the layering direction, in a case where a charge generation layer is interposed between the electroluminescent layers, when supply of carriers (electrons and/or holes) in the electroluminescent layer on one side in the layering direction with respect to the charge generation layer is optimized, supply of electrons and/or holes may be rate-controlled, that is, insufficient, in the electroluminescent layer on the other side. As a result, an imbalance in carrier balance may occur between the plurality of electroluminescent layers. In the disclosure, attention is paid to the fact that the supply of electrons is rate-controlled in the electroluminescent layer formed closer to the anode electrode layer than the charge generation layer by the supply amount of electrons supplied to an electroluminescent layer from the charge generation layer formed closer to the cathode electrode layer than the electroluminescent layer being smaller than the supply amount of holes supplied to an electroluminescent layer from the anode electrode layer or the charge generation layer formed closer to the anode electrode layer than the electroluminescent layer, and the carrier balance of all the electroluminescent layers in the layering direction is optimized by reducing the thickness of the electroluminescent layer on the anode electrode layer side where the supply of carriers (electrons) is rate-controlled.

That is, in the electroluminescent device of the disclosure, in at least one set of sets of the electroluminescent layers, each of the sets being two electroluminescent layers adjacent to each other with the charge generation layer interposed therebetween in the layering direction, the ratio of the thickness of the electroluminescent layer on the anode electrode layer side in the layering direction to the thickness of the electroluminescent layer on the cathode electrode layer side in the layering direction is larger than 1/15 and smaller than 4/15. That is, in the disclosure, the thickness of a specific electroluminescent layer is smaller than the thickness of the electroluminescent layer adjacent thereto on the cathode electrode layer side by the above-described ratio. Note that the expression “adjacent to each other” in the electroluminescent layer means a positional relationship in which the electroluminescent layers are adjacent to each other in the layering direction in the arrangement relationship between the electroluminescent layers included in the electroluminescent element. That is, another layer may be interposed between the electroluminescent layers adjacent to each other in the layering direction.

With such a configuration, in the electroluminescent device of the disclosure, the carrier balance in the electroluminescent layers in the layering direction is optimized. The thickness of each electroluminescent layer in the layering direction can be appropriately determined depending on various factors such as a combination of materials of the respective layers in the electroluminescent element and a purpose of changing the thickness of the electroluminescent layer as long as the technical idea of the disclosure is followed.

Note that when the ratio of the thickness of the electroluminescent layer on the anode electrode layer side in the layering direction to the thickness of the electroluminescent layer on the cathode electrode layer side in the layering direction is too small, the thickness of the electroluminescent layer on the anode electrode layer side becomes small, and the amount of light emission of the electroluminescent layer on the anode electrode layer side becomes small. Thus, the effect of the tandem structure including a plurality of electroluminescent layers in the layering direction is reduced. On the other hand, when the ratio is too large, the effect of correcting the carrier balance is small, and excess carriers (holes) are generated in the electroluminescent layer on the anode electrode layer side. Thus, a current that does not contribute to light emission is generated, which increases power consumption. The ratio is preferably larger than 1/15, more preferably 1/12 or more, and still more preferably 1/10 or more, from the viewpoint of making the amount of light emission of the electroluminescent layer on the anode electrode layer side a sufficient amount of light emission. In addition, the ratio is preferably smaller than 4/15, and more preferably 1/4 or less, from the viewpoint of suppressing the generation of excess carriers (holes). The ratio is more preferably 1/10 or more and more preferably 1/4 or less from the viewpoint of facilitating the change in thickness of each electroluminescent layer in the layering direction in addition to the viewpoint described above.

When a plurality of electroluminescent layers whose thicknesses change at the above-described ratio from the cathode electrode layer side to the anode electrode layer side are disposed in the layering direction, it is possible to significantly reduce the thickness of a useless portion of each electroluminescent layer, which does not contribute to light emission, and it is also possible to significantly reduce the material used for the electroluminescent layer. Thus, the drive voltage and the manufacturing costs can be significantly reduced. More specifically, in the electroluminescent device of the disclosure, the thickness of the electroluminescent layer on the anode electrode layer side where the supply amount of electrons is smaller than the supply amount of holes is made thinner. Thus, even when the amount of electrons supplied from the charge generation layer is small, the carrier balance in the electroluminescent layer on the anode electrode layer side can be made uniform, and the amount of excess holes in the electroluminescent layer on the anode electrode layer side can be reduced. This can reduce current consumption and improve luminous efficiency. Accordingly, the electroluminescent device of the disclosure having a tandem structure including a plurality of electroluminescent layers in the layering direction can further reduce the drive voltage, reduce the manufacturing costs, and improve the luminous efficiency, as compared with a known electroluminescent device having a separately applied RGB type tandem structure, which includes a plurality of electroluminescent layers having the same thickness.

Note that as for the thickness of each electroluminescent layer, the thickness of only an electroluminescent layer of one color of the electroluminescent device having the electroluminescent layers of a plurality of colors in the direction intersecting the layering direction may be changed at the above-described ratio, or the thicknesses of electroluminescent layers of any two or more colors may be uniformly or independently changed at the above-described ratio, within a range in which the effect of the disclosure is obtained. The ratios of the thicknesses of the electroluminescent layers in the layering direction may be constant for the respective luminescent colors, or may be different ratios within the above range.

The thickness of each electroluminescent layer in the layering direction can be determined to be a thickness tailored to the purpose by evaluation of a carrier injection property and/or a carrier transport property between the respective layers in the electroluminescent element by simulation and a demonstration experiment based on the evaluation. In this case, when the plurality of electroluminescent layers layered in the layering direction are set to have the same color, parameters of the carrier injection property and the carrier transport property between the electroluminescent layers different in the layering direction can be made the same. Thus, the simulation becomes easier, and the thickness of an electroluminescent layer can be determined more easily.

Preferable examples of the electroluminescent layer in the disclosure include a host/guest system electroluminescent layer including a host compound and a guest compound. The host/guest system electroluminescent layer includes, for example, a small amount (for example, about 0.1 to several mol %) of a fluorescent dopant as a guest compound in a solid medium which is a host compound. In the electroluminescent layer doped with the guest compound in this manner, the fluorescence of the host compound is completely lost, and instead, strong light emission corresponding to the fluorescence spectrum of the doped guest compound is obtained. This is because an excitation energy of the host compound is transferred to the guest compound. By this transfer of excitation energy, light emission from the guest compound having a higher quantum efficiency is obtained in the host/guest system electroluminescent layer.

In addition, the element lifetime of the electroluminescent element is also significantly improved by doping the electroluminescent layer with a fluorescent dopant as the guest compound. This is because the dopant, which is the guest compound, functions as a trap of carriers (electrons or holes) in the solid medium of the host compound to become a recombination center of the carriers, and directly creates excitons in the solid medium. A process of relaxation of the created excitons to the ground state is called a deactivation process. The deactivation process includes a non-radiative process (thermal deactivation) and a radiative process (light emission), and a phenomenon in which light emission is caused by the radiative process is electroluminescence. The guest compound functions as the trap of carriers, whereby not only the quantum efficiency of the electroluminescent layer but also the element lifetime due to improvement in recombination probability of carriers are improved. As a result, the luminous efficiency of the electroluminescent layer and the element lifetime of the electroluminescent element are improved.

As described above, effective use of carriers can be realized in the host/guest system electroluminescent layer, and thus, according to the electroluminescent device of the disclosure, high luminous efficiency of the electroluminescent layer and improvement of the element lifetime of the electroluminescent element can be realized.

Note that the excitons generated by carrier recombination include a singlet exciton and a triplet exciton. In a case where a fluorescent dopant is used as the guest compound, the singlet exciton contributes to light emission. Here, in a case where a phosphorescent dopant is used instead of the fluorescent dopant, the triplet exciton contributes to light emission. Generation proportions of singlet excitons and triplet excitons are 25% and 75%, respectively, according to a spin statistics law. Thus, in a case where the fluorescent dopant is used as the guest compound, that is, in the emission process of “fluorescence” emitted only from the singlet excitons, the probability of generating excitons that can contribute to light emission is at most 25%.

In contrast, in a case where the phosphorescent dopant is used as the guest compound, light can be extracted from the triplet excitons, and thus the quantum efficiency can be increased to three times that of the fluorescent dopant. Furthermore, when intersystem crossing, which is the inversion of spin from singlet excitons to triplet excitons, is utilized, all excitons generated can theoretically emit “phosphorescence” from the triplet excitons. Accordingly, in a case where the phosphorescent dopant is used as the guest compound, the quantum efficiency can be increased up to four times as compared with the case where the fluorescent dopant is used.

A known material can be used as the light emitting material of the electroluminescent layer. For example, examples of the light emitting material constituting a blue electroluminescent layer include a pyrene-based compound and an anthracene-based compound, which are fluorescent dopants. Examples of the light emitting materials constituting a red electroluminescent layer and a green electroluminescent layer include an iridium-based complex and a palladium-based complex, which are phosphorescent dopants.

Note that complexes including platinum group elements such as iridium or palladium used as phosphorescent dopants are very expensive even in a small amount, and there may be a difficulty in stable supply, because production amounts of platinum group elements are very small in combination with the fact that the production areas are unevenly distributed. Thus, it is extremely important to reduce the used amount of the phosphorescent dopant using these platinum-based complexes from the viewpoint of cost reduction and the viewpoint of economic security.

As described above, the host/guest system electroluminescent layer may be formed by doping the host compound with the guest compound. The host/guest system electroluminescent layer can be formed by a co-evaporation method using a plurality of vapor deposition sources.

As the material of the host/guest system electroluminescent layer, various known examples can be adopted. Examples of the host compound include known light emitting layer materials of respective colors. Examples of the guest compound include TADF and a hyperfluorescence material in addition to the fluorescent dopant and the phosphorescent dopant described above. Further examples of the fluorescent dopant include perylene, DPT, Coumarin 6, PMDFB, quinacridone, rubrene, BTX, ABTX, DCM, and DCJT. Further examples of the phosphorescent dopant include Ir(ppy)₃, Ir(thpy)₃, Ir(t5m-thpy)₃, Ir(t-5CF₃-py)₃, Ir(t-5t-py)₃, Ir(mt-5mt-py)₃, Ir(btpy)₃, Ir(tflpy)₃, Ir(piq)₃, Ir(tiq)₃, Ir(fliq)₃, FIrpic, FIr6, ppy, tpy, bzq, thp, op, bo, bt, bon, absn, btp, ppo, C6, pq, β-bsn, and ppz.

Note that in the currently mainstream electroluminescent element, the fluorescent dopant is used as the guest compound in an electroluminescent layer that emits blue light, and the phosphorescent dopant is used as the guest compound in electroluminescent layers that emit red and green light. In an electroluminescent device including these electroluminescent elements, both theoretically and in practice, the quantum efficiency of the fluorescent dopant is lower than that of the phosphorescent dopant. Accordingly, in the electroluminescent device, an amount of current flowing through the blue electroluminescent layer may be made greater than amounts of current flowing through the red and green electroluminescent layers to balance an amount of light emission.

However, when only the amount of current flowing through the blue electroluminescent layer, which is a fluorescent electroluminescent layer using the fluorescent dopant as the guest compound, is increased, the lifetime of the blue electroluminescent layer is inevitably shortened (the deterioration rate is increased). To address this problem, the total number of layers of the blue electroluminescent layer in the layering direction may be greater than the total number of layers of the red and green electroluminescent layers, which are phosphorescent electroluminescent layers in which the guest compound is the phosphorescent dopant. That is, the total number of the fluorescent electroluminescent layers may be greater than the total number of the phosphorescent electroluminescent layers. Such a configuration is advantageous in balancing the lifetimes of the electroluminescent layers and balancing the amounts of light emission, between the fluorescent electroluminescent layer and the phosphorescent electroluminescent layer in the electroluminescent element. The total number of the fluorescent electroluminescent layers is preferably greater than the total number of the phosphorescent electroluminescent layers by one or two. When the number of the fluorescent electroluminescent layers is greater than the number of the phosphorescent electroluminescent layers by three or more, it may be difficult to balance the lifetimes and the amounts of light emission between the phosphorescent electroluminescent layers of different colors. Alternatively, the balance of the element structure of the electroluminescent device is deteriorated, which may result in a low manufacturing yield.

### Charge Generation Layer

The charge generation layer is disposed between two electroluminescent layers adjacent to each other in the layering direction. The charge generation layer is a layer that generates one or both of an electron and a hole. The charge (charge or carrier) generated in the charge generation layer is supplied to the electroluminescent layer located on each of the anode electrode layer side and the cathode electrode layer side in the layering direction. For the charge generation layer, a known charge generation material that exhibits the above-described function can be adopted.

The charge generation layer may be composed of an electron generation layer that generates electrons and a hole generation layer that generates holes. Examples of the electron generation layer include an n-type charge generation layer, and examples of the hole generation layer include a p-type charge generation layer. When holes are supplied from the anode electrode layer and electrons are supplied from the cathode electrode layer, the n-type charge generation layer generates electrons and the p-type charge generation layer generates holes.

For the p-type charge generation layer, it is possible to use a material including an organic hole transport material and an organic electron accepting material (hole supply material) added in a range of 1 to 10%. As the organic hole transport material, a known triarylamine-based organic compound can be employed. Examples of the organic electron accepting material include tetracyanoquinodimethane tetrafluoride (TCNQ-4F). As the material of the p-type charge generation layer, a material having a sufficient hole generation capability is realized by using the above-described hole transport material, electron accepting material, and the like, and using all organic materials.

For the n-type charge generation layer, for example, it is possible to use a material including an organic electron transport material and Yb (ytterbium) or Li (lithium) that is an inorganic metal material added in a range of 5 to 20% and acts as an electron supply material.

Examples of the organic electron transport material include oxadiazole-based compounds. Also in the n-type charge generation layer, development is being advanced to use organic materials for both the electron transport material and the electron supply material. For example, as the organic electron supply material, BUPH1, BPen, p-MeO-Phen, p-NMe₂-Phen, p-Pyrrd-Phen, and the like are being developed.

At present, an organic electron supply material having a sufficient electron supply property that can be used for the n-type charge generation layer has not been found, and thus, an n-type charge generation layer that is entirely formed of an organic material and has sufficient characteristics has not been found. According to the disclosure, by setting the thickness of each electroluminescent layer in the layering direction as described above, the balance (carrier balance) between electrons and/or holes supplied from the charge generation layer and holes and/or electrons supplied from each electrode layer can be optimized. As a result, in the disclosure, an electroluminescent device having a tandem structure in which a plurality of electroluminescent layers are provided in the layering direction, the electroluminescent device suppressing generation of excess carriers and having excellent power consumption, is realized.

### Other Configurations

The electroluminescent element of the disclosure may further include another layer as long as the effect of the disclosure is obtained. Examples of other configurations include carrier function layers such as a hole injection layer, an electron injection layer, a hole transport layer, an electron blocking layer, a hole blocking layer, and an electron transport layer.

The hole injection layer is disposed adjacently to the anode electrode layer, for example. The hole injection layer may be composed of a hole transport material and an electron accepting material. These materials are the same organic materials as those described for the p-type charge generation layer, and the specific material of the hole injection layer in the electroluminescent element may be the same as or different from that of the p-type charge generation layer.

The electron injection layer is disposed adjacently to the cathode electrode layer, for example. The electron injection layer may be composed of an electron transport material. Examples of the electron transport material constituting the electron injection layer include lithium fluoride (LiF) which is an inorganic material. In addition, the electron injection layer may have a configuration in which an electron transport material is formed of an organic material such as an oxadiazole-based compound and a metal material (for example, Li, Yb, or the like) is doped thereto, similarly to the n-type charge generation layer.

LiF to be used for the electron injection layer exhibits an excellent electron injection property. On the other hand, the carrier function layer including an inorganic material such as Yb, not limited to LiF, is generally formed at a higher temperature than when the electroluminescent layer and the carrier function layer made of an organic material are formed, because the melting point of the inorganic material is high. This may thermally damage the organic material formed first. Thus, it is preferable to form the electroluminescent element only with the organic material as much as possible.

Accordingly, organic electron injection property materials such as BUPH1, BPen, p-MeO-Phen, p-NMe₂-Phen, and p-Pyrrd-Phen are being developed because they can have sufficient characteristics when combined with a cathode electrode layer composed of aluminum (Al) or the like, which can form a vapor deposition layer at a relatively low temperature.

However, the electron injection capability of the electron injection layer using an organic material is still inferior to that of the above-described electron injection layer using an inorganic material such as LiF. Thus, in a case where an electron injection layer made of an organic material is disposed adjacently to the cathode electrode layer, the amount of electrons supplied to the electroluminescent layer formed on the cathode electrode layer side may be reduced. In such a case, the thickness of the electroluminescent layer on the cathode electrode layer side is made smaller than the theoretical value to reduce the influence of the reduction in the amount of electrons supplied, whereby the advantage of the tandem structure can be sufficiently exhibited. For the imbalance of carrier balance in this case, it is effective to reduce the thickness of the electroluminescent layer on the anode electrode layer side at a specific ratio with respect to the thickness of the electroluminescent layer on the cathode electrode layer side, which is made thinner than the theoretical thickness. The disclosure may include such a configuration.

The hole transport layer may be composed of an organic hole transport material, for example, a triarylamine-based organic compound.

The electron blocking layer may also be composed of an organic hole transport material, as in the hole transport layer. The material of the electron blocking layer may be the same as or different from that of the hole transport layer.

The hole blocking layer may be composed of an organic electron transport material, for example, an oxadiazole-based compound. The material of the hole blocking layer may include lithium quinoline (Liq) in addition to the electron transport material.

The electron transport layer may be also composed of the organic electron transport material described above, as in the hole blocking layer. The material of the electron transport layer may be the same as or different from that of the hole blocking layer.

The hole injection layer and the electron injection layer only need to be disposed corresponding to the electrode layers, and are usually disposed adjacently to each electrode layer in the layering direction. The hole transport layer, the electron blocking layer, the above-described electroluminescent layer, the hole blocking layer, the electron transport layer, and the above-described charge generation layer may be repeatedly disposed a plurality of times in the layering direction of the electroluminescent element.

The electroluminescent device of the disclosure is suitable for a top emission type electroluminescent device capable of full color display. In the top emission type electroluminescent device, a light extraction efficiency may be increased by adjusting a distance between the electrode layers in accordance with a wavelength of light from the light emitting layer of each color and utilizing a microcavity effect. For this purpose, any of the carrier function layers may be thickened. The electroluminescent device of the disclosure has a so-called tandem structure including a plurality of electroluminescent layers and carrier function layers corresponding to the respective electroluminescent layers in the layering direction. Thus, thickening of the carrier function layer for adjusting the distance between the electrode layers is suppressed, which can further suppress consumption of functionally unnecessary materials.

### Stack

A stack is a layer set including one electroluminescent layer disposed between the anode electrode layer and the charge generation layer, between the charge generation layers, and between the charge generation layer and the cathode electrode layer in the layering direction. The stack may include a carrier function layer in addition to one electroluminescent layer. A plurality of stacks may be disposed between the anode electrode layer and the cathode electrode layer in the layering direction. Note that in the disclosure, the anode electrode layer, the cathode electrode layer, and the charge generation layer are not included in the stack.

The thickness of the stack is determined in such a manner that the amount of light emitted in the electroluminescent layer is at or near a theoretical value. In the disclosure, the thickness of each electroluminescent layer in the layering direction may be set within the range of the proportion of the above-described ratio, and thus, it is preferable to set the thickness of the stack depending on the thickness of the electroluminescent layer set in this manner from the viewpoint of increasing the luminous efficiency of the electroluminescent element. From such a viewpoint, the ratio of the thickness of the electroluminescent layer in the stack to the thickness of the stack in the layering direction is preferably 0.03 or more and 0.75 or less. Note that the thickness of the stack is determined by the sum of the thicknesses of the electroluminescent layer and the carrier function layer in the stack, but a layer having a very small thickness (for example, a layer having a thickness that may be less than 1 nm) among the electroluminescent layer and the carrier function layer may be ignored when the thickness of the stack is calculated.

### Method for Manufacturing Electroluminescent Device

In manufacturing of the electroluminescent device of the disclosure, the thicknesses of the electroluminescent layers are controlled in such a manner that the ratio of the thickness of the electroluminescent layer on the anode electrode layer side in the layering direction to the thickness of the electroluminescent layer on the cathode electrode layer side in the layering direction, the electroluminescent layers being adjacent to each other with the charge generation layer interposed therebetween in the layering direction, is larger than 1/15 and smaller than 4/15. Otherwise, the electroluminescent element of the disclosure can be manufactured by a known production method capable of manufacturing an electroluminescent device having a plurality of electroluminescent layers (tandem structure). The method for manufacturing the electroluminescent device only needs to be a method including a step of alternately forming an electroluminescent layer and a charge generation layer on an anode electrode layer or a cathode electrode layer in a layering direction. In addition, from the viewpoint of precisely controlling the thickness of each electroluminescent layer in the electroluminescent device of the disclosure, it is preferable that at least the electroluminescent layer is formed by a vapor deposition method in the manufacturing method. The electroluminescent layer formed by the vapor deposition method is generally preferred from the viewpoint of achieving high luminance and low voltage driving, and is also preferred from the viewpoint of realizing a high resolution display device because an electroluminescent element composed of fine pixels can be formed with high accuracy. In addition, a co-evaporation method using a plurality of vapor deposition sources is more preferable because a host/guest system electroluminescent layer can be formed.

The electroluminescent device of the disclosure has a specific layer configuration repeatedly, and thus, can be manufactured by repeating formation of a specific layer a plurality of times. In the disclosure, the electroluminescent layers having different thicknesses in the layering direction are preferably formed by changing only the vapor deposition time. According to such a manufacturing method, it is possible to make constant conditions other than the time of vapor deposition in the formation of the electroluminescent layer (for example, a temperature of a crucible (vapor deposition temperature), a vapor deposition rate controlled by the vapor deposition temperature or the like, proportions of the host compound and the guest compound (doping concentration of the guest compound), a vapor deposition mask defining a pixel shape, and the like). Accordingly, variation in characteristics due to the change in conditions in each electroluminescent layer in the layering direction is suppressed, and the effect due to the difference in thickness of the electroluminescent layers in the layering direction can be more remarkably exhibited.

### Display Device

A display device according to the disclosure includes the above-described electroluminescent device. The display device of the disclosure can be configured in the same manner as a known display device including a known light emitting device except that the display device of the disclosure includes the above-described electroluminescent device. Examples of the display device include a television device and a smartphone.

### Description of Specific Aspects

Hereinafter, the electroluminescent device, the method for manufacturing the same, and the display device of the disclosure will be described more specifically with reference to the drawings, taking an electroluminescent device including an organic light emitting diode (OLED) as an example. In the present specification, configurations related to different colors among similar basic configurations are denoted by reference signs indicating colors added to reference signs of the basic configurations. For example, a configuration related to red is denoted by adding R, a configuration related to green is denoted by adding G, and a configuration related to blue is denoted by adding B.

### First Embodiment

### Configuration

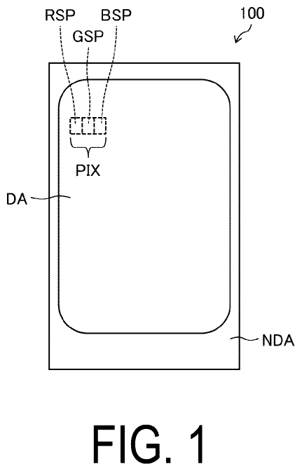

FIG. 1 is a plan view schematically illustrating a configuration of a display device 100 according to a first embodiment of the disclosure. FIG. 1 illustrates a smartphone as an example of the display device. As illustrated in FIG. 1, a display device 100 includes a frame region NDA and a display region DA. A plurality of pixels PIX are provided in the display region DA of the display device 100, and each pixel PIX includes a red subpixel RSP, a green subpixel GSP, and a blue subpixel BSP.

Note that the configuration of the pixel of the display device in the disclosure is not limited to the above-described configuration. In the display device of the disclosure, for example, one pixel PIX may further include a subpixel of another color in addition to the red subpixel RSP, the green subpixel GSP, and the blue subpixel BSP.

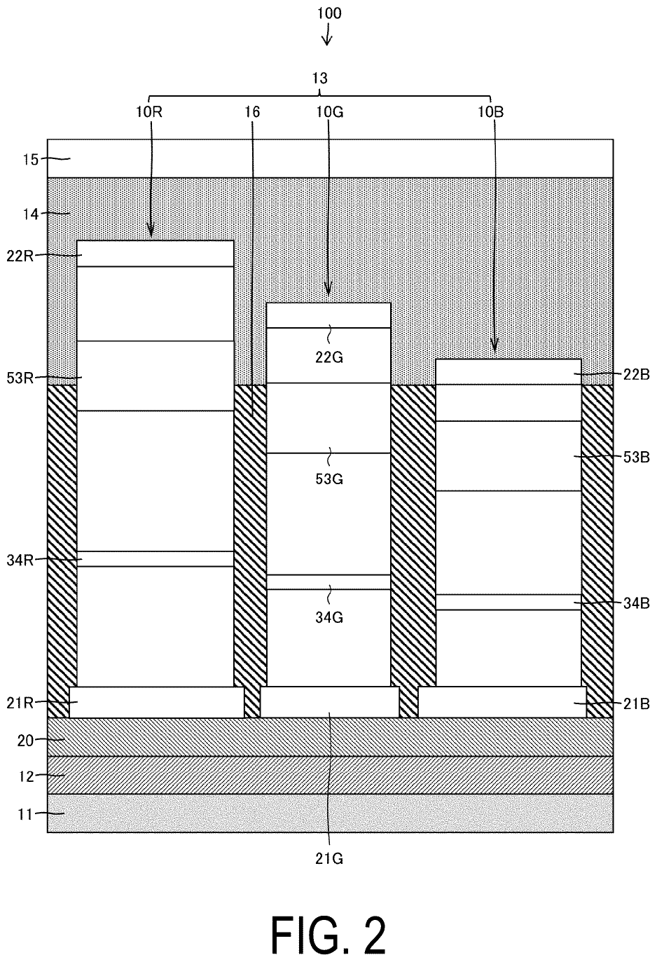

FIG. 2 is a diagram schematically illustrating the layer configuration of the display device 100 in FIG. 1. As illustrated in FIG. 2, in the display device 100, a substrate 11, a buffer layer 12, a thin film transistor (TFT) layer 20 including a pixel circuit, an electroluminescent device 13 and an edge cover film 16, a sealing layer 14, and an external function layer 15 are layered in this order.

The substrate 11 is a glass substrate or a flexible substrate including resin such as polyimide as a main component, and for example, the substrate 11 may be constituted by two layers of polyimide films and an inorganic film interposed therebetween. The buffer layer 12 can be constituted by an inorganic insulating layer that prevents penetration of foreign matters such as water and oxygen. The TFT layer 20 includes pixel circuits for controlling a red electroluminescent element 10R, a green electroluminescent element 10G, and a blue electroluminescent element 10B.

The electroluminescent device 13 includes the red electroluminescent element 10R, the green electroluminescent element 10G, and the blue electroluminescent element 10B. The red electroluminescent element 10R includes an anode electrode layer 21R and a cathode electrode layer 22R, and includes a first electroluminescent layer 34R and a second electroluminescent layer 53R between these electrode layers. Similarly, the green electroluminescent element 10G includes an anode electrode layer 21G, a first electroluminescent layer 34G, a second electroluminescent layer 53G, and a cathode electrode layer 22G, and the blue electroluminescent element 10B includes an anode electrode layer 21B, a first electroluminescent layer 34B, a second electroluminescent layer 53B, and a cathode electrode layer 22B.

Here, FIG. 2 illustrates a configuration in which the cathode electrode layer 22R, the cathode electrode layer 22G, and the cathode electrode layer 22B are provided in the red electroluminescent element 10R, the green electroluminescent element 10G, and the blue electroluminescent element 10B, respectively. The electroluminescent device 13 of the disclosure is not limited to this configuration. For example, the cathode electrode layer 22R, the cathode electrode layer 22G, and the cathode electrode layer 22B may be a common electrode layer provided across the red electroluminescent element 10R, the green electroluminescent element 10G, and the blue electroluminescent element 10B.

The sealing layer 14 covering the electroluminescent device 13 is a layer that prevents penetration of foreign matter such as water or oxygen into the electroluminescent device 13, and for example, the sealing layer 14 can include two inorganic sealing films and an organic film formed therebetween. The external function layer 15 is a layer that adds various functions such as optical control, a touch sensor, and surface protection to the display device 100.

The edge cover film 16 is insulative and covers edges of the respective anode electrode layers 21R, 21G, and 21B. The edge cover film 16 is formed by applying an organic material such as polyimide or acrylic resin and then patterning the organic material by photolithography, for example. Note that the red electroluminescent element 10R, the green electroluminescent element 10G, and the blue electroluminescent element 10B are, for example, organic light emitting diodes (OLEDs).

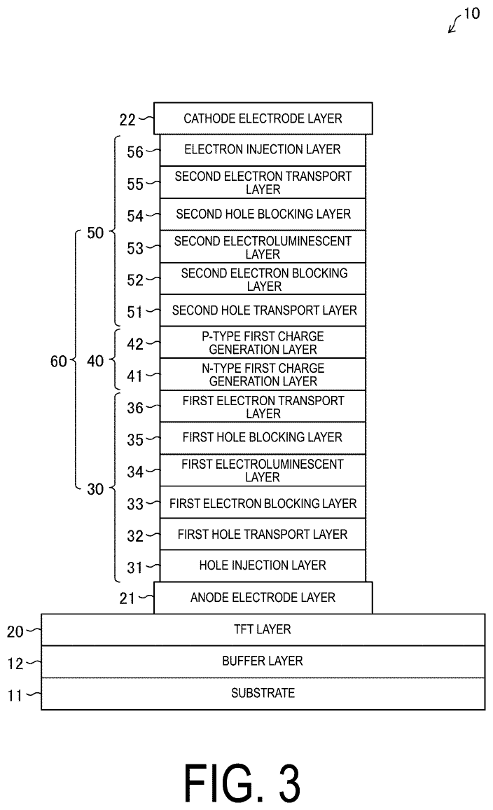

The element configuration of the electroluminescent element 10 illustrated in FIG. 2 will be described with reference to FIG. 3. FIG. 3 is a diagram schematically illustrating the layer configuration of the electroluminescent element in the layer configuration illustrated in FIG. 2.

As illustrated in FIG. 3, the substrate 11, the buffer layer 12, and the TFT layer 20 are layered in this order, and the electroluminescent element 10 is configured by layering the anode electrode layer 21, a layer set 30, the first charge generation layer 40, a layer set 50, and the cathode electrode layer 22 on the TFT layer 20 in this order. The electroluminescent element 10 according to the disclosure is of a top emission type (a structure in which light is extracted from the upper side, that is, the cathode electrode layer 22 side). In the electroluminescent element 10, for example, the anode electrode layer 21 functions as an anode, and the cathode electrode layer 22 functions as a cathode.

The layer set 30 includes a hole injection layer 31, a first hole transport layer 32, a first electron blocking layer 33, a first electroluminescent layer 34, a first hole blocking layer 35, and a first electron transport layer 36. The layer set 50 includes a second hole transport layer 51, a second electron blocking layer 52, a second electroluminescent layer 53, a second hole blocking layer 54, a second electron transport layer 55, and an electron injection layer 56. Between the layer set 30 and the layer set 50, a first charge generation layer 40 is disposed, which includes an n-type first charge generation layer (electron generation layer) 41 and a p-type first charge generation layer (hole generation layer) 42. In the electroluminescent element 10 of FIG. 3, the layer set 30 is also referred to as a “first stack” and the layer set 50 is also referred to as a “second stack”. An organic layered body 60 is comprised of the layer set 30, the first charge generation layer 40, and the layer set 50.

The hole injection layer 31, the first hole transport layer 32, the first electron blocking layer 33, the first hole blocking layer 35, the first electron transport layer 36, the n-type first charge generation layer 41, the p-type first charge generation layer 42, the second hole transport layer 51, the second electron blocking layer 52, the second hole blocking layer 54, the second electron transport layer 55, and the electron injection layer 56 are carrier function layers that contribute to at least one of injection, transport, or generation of carriers (electrons or holes).

The electroluminescent element 10 is an electroluminescent element having a so-called tandem structure in which two electroluminescent layers of the first electroluminescent layer 34 and the second electroluminescent layer 53 are disposed between the anode electrode layer 21 and the cathode electrode layer 22 in the layering direction. The first electroluminescent layer 34 and the second electroluminescent layer 53 that overlap in the layering direction are electroluminescent layers that emit light of the same color.

The thickness of the second electroluminescent layer 53 varies depending on the luminescent color, and for example, the thickness of the second electroluminescent layer 53 of each of the red electroluminescent element and the green electroluminescent element is 20 nm to 80 nm, and the thickness of the second electroluminescent layer 53 of the blue electroluminescent element is 15 to 45 nm. A ratio (T1/T2) of a thickness (T1) of the first electroluminescent layer 34 to a thickness (T2) of the second electroluminescent layer 53 is larger than 1/15 and smaller than 4/15. More preferably, the ratio of the thickness of the first electroluminescent layer 34 to the thickness of the second electroluminescent layer 53 is 1/10 or more and 1/4 or less. Both the first electroluminescent layer 34 and the second electroluminescent layer 53 are host/guest system electroluminescent layers.

### Method for Manufacturing Electroluminescent Element

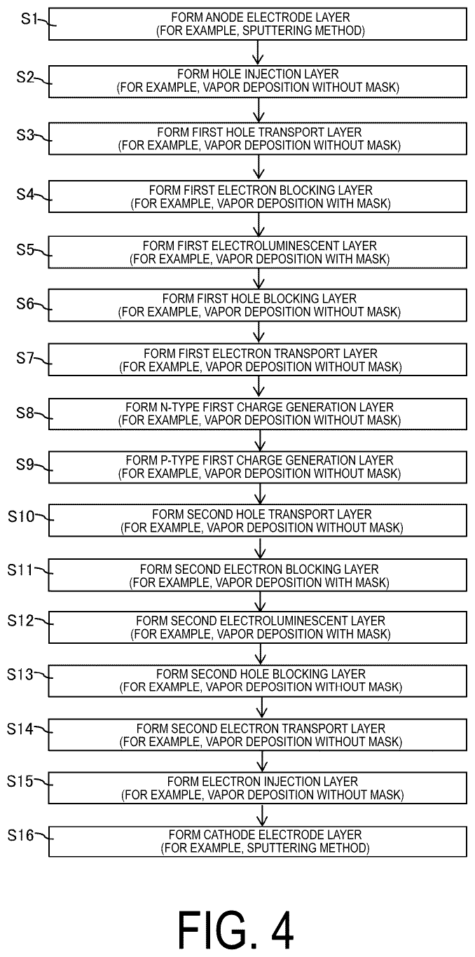

Next, an example of a method for manufacturing the electroluminescent element 10 will be described below with reference to FIG. 4. FIG. 4 is a flowchart illustrating an example of the method for manufacturing the electroluminescent element illustrated in FIG. 3.

As illustrated in FIG. 4, in step S1, the anode electrode layer 21 is formed on the TFT layer 20. Specifically, an Ag layer and an In—Sn—O layer are sequentially formed by a sputtering method.

In step S2, the hole injection layer 31 is formed on the anode electrode layer 21. Specifically, the hole transport material and the electron accepting material are co-evaporated at a predetermined vapor deposition rate by adjusting the vapor deposition temperature and the vapor deposition time of each material in such a manner that the materials are layered with a predetermined film thickness and proportions. Here, a vapor deposition film is formed uniformly on the entire surface of a workpiece without using a fine metal mask.

Note that in the specific description of the manufacturing method based on FIG. 4, a common layer is formed between the electroluminescent elements of all colors for some of the carrier function layers, but the manufacturing method of the disclosure is not limited thereto. The thicknesses of the respective carrier function layers may be different for each color, for example, depending on the electroluminescent layers of the respective colors. Such a carrier function layer with a locally varying thickness can be formed by vapor deposition through a mask.

In step S3, the first hole transport layer 32 is formed on the hole injection layer 31. Specifically, the hole transport material is vapor-deposited at a predetermined vapor deposition rate by adjusting the vapor deposition temperature and the vapor deposition time to form a layer having a predetermined thickness. Here, the vapor deposition film is formed without using a fine metal mask.

In step S4, the first electron blocking layer 33 is formed on the first hole transport layer 32. Specifically, the hole transport material is vapor-deposited at a predetermined vapor deposition rate by adjusting the vapor deposition temperature and the vapor deposition time to form a layer having a predetermined thickness. Here, a fine metal mask is used, and vapor deposition is performed to form a layer having a first thickness corresponding to each color. The first thickness may be the same or different for the electroluminescent elements of the respective colors.

In step S5, the first electroluminescent layer 34 is formed on the first electron blocking layer 33. Specifically, co-evaporation of the host compound and the guest compound (dopant) is performed at a predetermined vapor deposition rate by adjusting the vapor deposition temperature and the vapor deposition time of each of the host compound and the guest compound to form a layer having a predetermined thickness and a predetermined concentration of the guest compound concentration (dopant concentration). Here, a fine metal mask is used, and materials corresponding to the respective colors are vapor-deposited while precisely controlling the respective thicknesses and the guest compound concentrations. At this time, the first electroluminescent layer 34 is vapor-deposited in such a manner that the ratio of the thickness of the first electroluminescent layer 34 to the thickness of the second electroluminescent layer 53 is larger than 1/15 and smaller than 4/15. More preferably, the ratio of the thickness of the first electroluminescent layer 34 to the thickness of the second electroluminescent layer 53 is 1/10 or more and 1/4 or less. In addition, the first electroluminescent layer 34 is vapor-deposited in such a manner that the ratio of the thickness of the first electroluminescent layer 34 to the thickness of the layer set 30 in the layering direction is 0.03 or more and 0.75 or less.

In step S6, the first hole blocking layer 35 is formed on the first electroluminescent layer 34. Specifically, the electron transport material is vapor-deposited at a predetermined vapor deposition rate by adjusting the vapor deposition temperature and the vapor deposition time to form a layer having a predetermined thickness. Here, the vapor deposition film is formed without using a fine metal mask.

In step S7, the first electron transport layer 36 is formed on the first hole blocking layer 35. Specifically, the electron transport material is vapor-deposited at a predetermined vapor deposition rate by adjusting the vapor deposition temperature and the vapor deposition time to form a layer having a predetermined thickness. The vapor deposition may be co-evaporation of the electron transport material and lithium quinoline. Here, the vapor deposition film is formed without using a fine metal mask.

In step S8, the n-type first charge generation layer 41 is formed on the first electron transport layer 36. Specifically, the organic electron transport material and Yb or Li, which is an inorganic metal material and an electron supply material, are co-evaporated at a predetermined vapor deposition rate by adjusting the vapor deposition temperature and the vapor deposition time to form a layer having a predetermined film thickness and proportions. Here, the vapor deposition film is formed without using a fine metal mask.

In step S9, the p-type first charge generation layer 42 is formed on the n-type first charge generation layer 41. Specifically, the organic hole transport material and the organic electron accepting material are co-evaporated at a predetermined vapor deposition rate by adjusting the vapor deposition temperature and the vapor deposition time of each material to form a layer having a predetermined film thickness and proportions. Here, the vapor deposition film is formed without using a fine metal mask.

In step S10, the second hole transport layer 51 is formed on the p-type first charge generation layer 42. Specifically, the hole transport material is vapor-deposited at a predetermined vapor deposition rate by adjusting the vapor deposition temperature and the vapor deposition time to form a layer having a predetermined thickness. Here, the vapor deposition film is formed without using a fine metal mask.

In step S11, the second electron blocking layer 52 is formed on the second hole transport layer 51. Specifically, the hole transport material is vapor-deposited at a predetermined vapor deposition rate by adjusting the vapor deposition temperature and the vapor deposition time to form a layer having a predetermined thickness. Here, a fine metal mask is used, and vapor deposition is performed to form a layer having a second thickness corresponding to each color. The second thickness may be the same or different for the electroluminescent elements of the respective colors, as with the first thickness.

In step S12, the second electroluminescent layer 53 is formed on the second electron blocking layer 52. Specifically, co-evaporation of the host compound and the guest compound (dopant) is performed at a predetermined vapor deposition rate by adjusting the vapor deposition temperature and the vapor deposition time of each of the host compound and the guest compound to form a layer having a predetermined thickness and a predetermined concentration of the guest compound concentration (dopant concentration). Here, a fine metal mask is used, and materials corresponding to the respective colors are vapor-deposited while precisely controlling the respective thicknesses and the guest compound concentrations. Furthermore, the second electroluminescent layer 53 is vapor-deposited in such a manner that the ratio of the thickness of the second electroluminescent layer 53 to the thickness of the layer set 50 in the layering direction is 0.03 or more and 0.75 or less.

In step S13, the second hole blocking layer 54 is formed on the second electroluminescent layer 53. Specifically, the electron transport material is vapor-deposited at a predetermined vapor deposition rate by adjusting the vapor deposition temperature and the vapor deposition time to form a layer having a predetermined thickness. Here, the vapor deposition film is formed without using a fine metal mask.

In step S14, the second electron transport layer 55 is formed on the second hole blocking layer 54. Specifically, the electron transport material is vapor-deposited at a predetermined vapor deposition rate by adjusting the vapor deposition temperature and the vapor deposition time to form a layer having a predetermined thickness. The electron transport material and lithium quinoline may be co-evaporated. Here, the vapor deposition film is formed without using a fine metal mask.

In step S15, the electron injection layer 56 is formed on the second electron transport layer 55. Specifically, lithium fluoride is vapor-deposited at a predetermined vapor deposition rate by adjusting the vapor deposition temperature and the vapor deposition time to form a layer having a predetermined thickness. Here, the vapor deposition film is formed without using a fine metal mask.

In step S16, the cathode electrode layer 22 is formed on the electron injection layer 56.

Specifically, a magnesium-silver alloy thin film is formed by using a vapor deposition method, for example.

### Mechanism of Light Emission

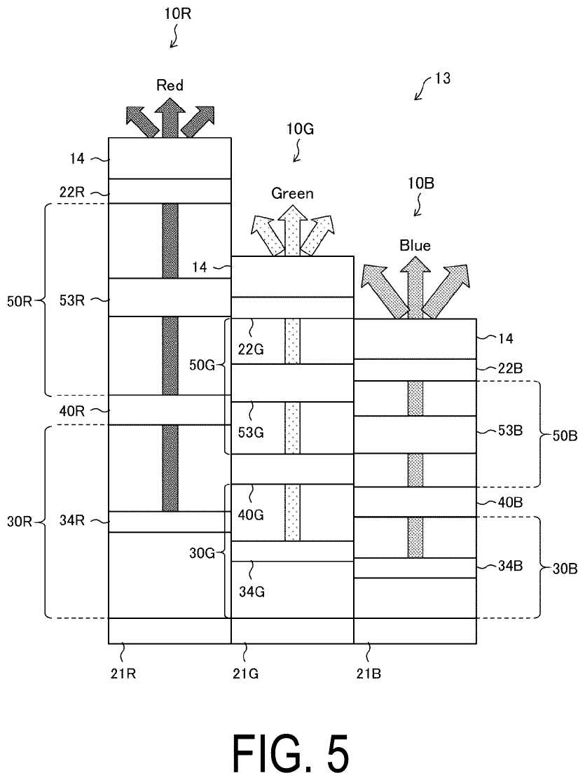

With reference to FIG. 5, a light emission mechanism of the electroluminescent element 10 of the electroluminescent device 13 capable of full color display will be described. FIG. 5 is a diagram for explaining the light emission mechanism of the electroluminescent element 10 of the electroluminescent device 13 illustrated in FIG. 2. In FIG. 5, only a main part of the configuration of the electroluminescent element 10 is illustrated.

The electroluminescent element 10 illustrated in FIG. 5 is an organic-EL element having a tandem structure in which two electroluminescent layers, namely, the first electroluminescent layer 34 and the second electroluminescent layer 53, are formed between the anode electrode layer 21 and the cathode electrode layer 22. The first charge generation layer 40 is disposed between the first electroluminescent layer 34 and the second electroluminescent layer 53. In the example illustrated in FIG. 5, the first electroluminescent layer 34 and the second electroluminescent layer 53 that emit light of the same color are layered for each of the red electroluminescent element 10R, the green electroluminescent element 10G, and the blue electroluminescent element 10B.

More specifically, as illustrated in FIG. 5, in the red electroluminescent element 10R, the anode electrode layer 21R, the first electroluminescent layer 34R, the first charge generation layer 40R, the second electroluminescent layer 53R, and the cathode electrode layer 22R are disposed in this order. In the red electroluminescent element 10R, a layer set 30R including the first electroluminescent layer 34R, which is disposed between the anode electrode layer 21R and the first charge generation layer 40R in the layering direction, is a first stack. A layer set 50R including the second electroluminescent layer 53R, which is disposed between the first charge generation layer 40R and the cathode electrode layer 22R, is a second stack.

Similarly, in the green electroluminescent element 10G, the anode electrode layer 21G, the first electroluminescent layer 34G, the first charge generation layer 40G, the second electroluminescent layer 53G, and the cathode electrode layer 22G are disposed in this order. The first stack in the green electroluminescent element 10G is a layer set 30G including the first electroluminescent layer 34G, which is disposed between the anode electrode layer 21G and the first charge generation layer 40G in the layering direction. The second stack in the green electroluminescent element 10G is a layer set 50G including the second electroluminescent layer 53G, which is disposed between the first charge generation layer 40G and the cathode electrode layer 22G.

In the blue electroluminescent element 10B, the anode electrode layer 21B, the first electroluminescent layer 34B, the first charge generation layer 40B, the second electroluminescent layer 53B, and the cathode electrode layer 22B are layered in this order. The first stack in the blue electroluminescent element 10B is a layer set 30B including the first electroluminescent layer 34B, which is disposed between the anode electrode layer 21B and the first charge generation layer 40B in the layering direction. The second stack in the blue electroluminescent element 10B is a layer set 50B including the second electroluminescent layer 53B, which is disposed between the first charge generation layer 40B and the cathode electrode layer 22B.

Here, the cathode electrode layers 22R, 22G, and 22B are provided in the red electroluminescent element 10R, the green electroluminescent element 10G, and the blue electroluminescent element 10B, respectively. The cathode electrode layers 22R, 22G, and 22B may be a common electrode layer provided across the red electroluminescent element 10R, the green electroluminescent element 10G, and the blue electroluminescent element 10B.

Further, in FIG. 5, the sealing layer 14 is illustrated, the sealing layer 14 being provided on the uppermost portion of each of the red electroluminescent element 10R, the green electroluminescent element 10G, and the blue electroluminescent element 10B to prevent penetration of oxygen and moisture. The sealing layer 14 may also be a common layer provided across the red electroluminescent element 10R, the green electroluminescent element 10G, and the blue electroluminescent element 10B.

Note that in the layer sets 30R, 30G, and 30B, and the layer sets 50R, 50G, and 50B included in the electroluminescent elements 10R, 10G, and 10B of the respective colors, carrier function layers (electron injection layer, electron transport layer, hole transport layer, hole injection layer, and the like), which are not illustrated, are disposed.

Hereinafter, the light emission mechanism of the electroluminescent element 10 will be further described. In the following description, the red electroluminescent element 10R, the green electroluminescent element 10G, and the blue electroluminescent element 10B have the same light emission mechanism, and thus, the reference signs R, G, and B indicating colors added to the reference signs indicating the basic configurations will be omitted.

When a current flows through the electroluminescent element 10, holes are supplied from the anode electrode layer 21 to the first electroluminescent layer 34, and electrons are supplied from the cathode electrode layer 22 to the second electroluminescent layer 53. Furthermore, when a current flows through the electroluminescent element 10, electrons generated by the n-type first charge generation layer 41 are supplied to the first electroluminescent layer 34, and holes generated by the p-type first charge generation layer 42 are supplied to the second electroluminescent layer 53.

As a result, electrons and holes recombine in the first electroluminescent layer 34 to generate electron-hole pairs (or also referred to as excitons), and the electron-hole pairs transition to a ground state, thereby emitting light in a predetermined wavelength range. In addition, in the second electroluminescent layer 53 as well, electrons and holes recombine to generate electron-hole pairs, and the electron-hole pairs transition to the ground state, thereby emitting light in a predetermined wavelength range (light of the same color as the first electroluminescent layer 34). For example, the first electroluminescent layer 34R and the second electroluminescent layer 53R of the red electroluminescent element 10R each emit red light. Similarly, the first electroluminescent layer 34G and the second electroluminescent layer 53G of the green electroluminescent element 10G each emit green light, and the first electroluminescent layer 34B and the second electroluminescent layer 53B of the blue electroluminescent element 10B each emit blue light.

At the time, both the first electroluminescent layer 34 and the second electroluminescent layer 53 may emit light with luminous efficiency substantially equal to a theoretical value. Thus, all of the plurality of light emitting layers of the same color disposed in the layering direction emit light substantially equal to the theoretical value, and are used for forming a high luminance and high resolution full color image.

However, an amount of light emitted from a known electroluminescent element that does not have the configuration of the electroluminescent layer as described in the disclosure, that is, has a known tandem structure in which two host/guest system electroluminescent layers that emit light of the same color are layered with the same thickness, may not reach 2 times the amount of light emitted from an electroluminescent element having a single electroluminescent layer (that is, the theoretical value).

Here, the results of verification by the present inventors will be introduced. First, an electroluminescent element (single prototype) including a single blue electroluminescent layer (or also referred to as a single layer; single structure) and an electroluminescent element (comparative tandem prototype) having a tandem structure including two of the blue electroluminescent layers were experimentally produced. The single prototype was manufactured under the following conditions. The comparative tandem prototype was manufactured under three types of conditions, i.e., the following conditions i to iii. The single prototype had the same layer configuration as the first stack of condition i between the cathode electrode layer and the anode electrode layer. The comparative tandem prototype was an electroluminescent element including the electroluminescent layers layered in the layering direction of the same thickness, that is, having a known tandem structure. Then, the element lifetime and the drive voltage were measured for each prototype, and the current efficiencies were determined using the Blue Index (unit: cd/A/y, y is one of the chromaticity coordinates in CIE1931).

### Single Prototype

Layer configuration: Cathode electrode layer/first stack (electron transport layer/hole blocking layer/first blue electroluminescent layer (thickness: 15 nm)/electron blocking layer/hole transport layer/hole injection layer)/anode electrode layer Ratio of thicknesses: The ratio of the thickness of the first electroluminescent layer (15 nm) to the first stack thickness (165 nm) is 0.091.

### Condition I

Layer configuration: Cathode electrode layer/second stack (electron injection layer/electron transport layer/hole blocking layer/second blue electroluminescent layer (thickness: 15 nm)/hole transport layer/hole injection layer)/charge generation layer/first stack (electron transport layer/hole blocking layer/first blue electroluminescent layer (thickness: 15 nm)/electron blocking layer/hole transport layer/hole injection layer)/anode electrode layer Ratio of thicknesses: The ratio of the thickness (15 nm) of the second electroluminescent layer to the thickness of the second stack (70 nm) is 0.21, and the ratio of the thickness (15 nm) of the first electroluminescent layer to the thickness of the first stack (165 nm) is 0.091.

### Condition II

### Layer Configuration: Same as Condition I

Ratio of thicknesses: Same as condition i except that the thickness of the carrier function layer in the second stack layer was adjusted to make the total thickness 80 nm. The ratio of the thickness (15 nm) of the second electroluminescent layer to the thickness (80 nm) of the second stack layer is 0.188.

### Condition III

### Layer Configuration: Same as Condition I

Ratio of thicknesses: Same as condition i except that the thickness of the carrier function layer in the second stack layer was adjusted to make the total thickness 90 nm. The ratio of the thickness (15 nm) of the second electroluminescent layer to the thickness (90 nm) of the second stack layer is 0.167.

As a result, the current efficiency of the single prototype was 206cd/A/y. In contrast, the current efficiencies of the comparative tandem prototypes were (condition i) 305cd/A/y (1.48 times that of the single prototype), (condition ii) 320cd/A/y (1.55 times that of the single prototype), and (condition iii) 219cd/A/y (1.1 times that of the single prototype). In measurement of element lifetimes, the element lifetimes of the comparative tandem prototypes were 2.01 times (condition i), 2.12 times (condition ii), and 1.92 times (condition iii) that of the single prototype. Further, in measurement of drive voltages, the drive voltages of the comparative tandem prototypes were 1.9 times (condition i), 1.9 times (condition ii), and 2.0 times (condition iii) that of the single prototype.

From the above results, it is found that the electroluminescent elements each having the known tandem structure including two electroluminescent layers, in which the thicknesses of the electroluminescent layers are the same and the conditions of the carrier function layers other than the electroluminescent layers are changed, have an element lifetime improved to about 2 times that of the electroluminescent element having a single structure including a single electroluminescent layer. On the other hand, it is found that the electroluminescent elements each having the known tandem structure including two electroluminescent layers with the same thickness have a smaller increase in current efficiency than an increase in drive voltage as compared with the electroluminescent element having the single structure, and even when the conditions of the carrier function layers are changed, the luminous efficiency does not reach 2 times that of the electroluminescent element having the single structure even though the drive voltage is about 2 times as high.

Based on these results, it is considered that a higher drive voltage is applied and a larger current is supplied as a countermeasure for making the luminous efficiency of the known electroluminescent element having two electroluminescent layers (tandem structure) 2 times that of the electroluminescent element having the single structure (that is, electroluminescent element having a single electroluminescent layer), but it is obvious that this results in an increase in power consumption and a decrease in element lifetime. That is, it is understood that there is room for study in the known structure to sufficiently exhibit the advantage of adopting the tandem structure. According to the studies of the present inventors regarding this, the following reasons are considered.

In an organic material, generally, the mobility of holes is higher than the mobility of electrons in many cases, and as a result, the supply amount of electrons is likely to be rate-controlled in the generation of excitons. Conversely, the supply of holes is likely to be excessive. In the known electroluminescent element having a single electroluminescent layer, the amounts of carriers supplied in the electroluminescent layer are made to coincide, that is, the carrier balance is achieved, by material selection of the carrier function layers other than the electroluminescent layer or optimization of the thicknesses of the carrier function layers. In the related art, to solve the problem of the carrier balance of the individual electroluminescent layers in the electroluminescent element having a tandem structure, the same measures as those of the electroluminescent element having a single electroluminescent layer, that is, the optimization of the carrier function layer around the electroluminescent layer other than the electroluminescent layer as described above has been taken. However, in an electroluminescent element including a plurality of electroluminescent layers (tandem structure), a charge generation layer is interposed between two electroluminescent layers adjacent to each other in the layering direction, but the balance between electrons and holes generated by the charge generation layer may not be usually 1:1.

Further, the n-type charge generation layer is mainly of an organic-inorganic hybrid configuration in which an organic electron transport material is doped with a small amount of a metal material, but in recent years, from the viewpoint of preventing deterioration of organic materials included in other layers due to an increase in vapor deposition temperature, development of an n-type charge generation layer having a configuration including only an organic material as in the p-type charge generation layer has been advanced. However, under the current conditions, the amount of electrons supplied from the n-type charge generation layer, which is entirely composed of an organic material, may be significantly smaller than the amount of holes supplied from the p-type charge generation layer. Because of these phenomena, it is difficult to make the supply amounts of electrons and holes equal between two electroluminescent layers adjacent to each other with the charge generation layer interposed therebetween in the layering direction in the electroluminescent element having a tandem structure.

That is, as shown in the above-described verification results, the electroluminescent element having a tandem structure may not be sufficient with the effect of optimizing the carrier function layer around the electroluminescent layer other than the electroluminescent layer, which has been performed in the related art. In addition, there is room for study for measures against a new problem that the amount of light emitted from the known electroluminescent element having a tandem structure including two electroluminescent layers with the same thickness may not reach 2 times the amount of light emitted from the electroluminescent element including a single electroluminescent layer.

To solve the problem, the present inventors have focused attention on the mobility of carriers in the layering direction of the electroluminescent element including a plurality of electroluminescent layers (tandem structure) and the injection property of carriers, and further on the amount of carriers supplied and the amount of excess carriers generated in each electroluminescent layer. As a result, the present inventors have found that, in a plurality of electroluminescent layers layered with the charge generation layer interposed therebetween, in a case where the supply amount of electrons in the electroluminescent layer closer to the anode electrode layer is rate-controlled, the amount of carriers (electrons) supplied to the electroluminescent layer layered closer to the anode electrode layer is smaller than the amount of carriers (electrons) supplied to the electroluminescent layer layered closer to the cathode electrode layer. In particular, it has been found that in a case where the n-type charge generation layer includes an organic electron supply material, the amount of carriers (electrons) supplied to the electroluminescent layer layered closer to the anode electrode layer is reduced. Thus, the supply amount of electrons that can be combined with holes in the electroluminescent layer layered closer to the anode electrode layer is reduced, and the amount of electron-hole pairs (excitons) generated by recombination is relatively reduced. That is, even if there are a plurality of electroluminescent layers in the layering direction (even if the thickness of the electroluminescent layers is a plurality of times the thickness of each electroluminescent layer), the amount of excitons does not reach a plurality of times. The present inventors have found that as a result, the amount of light emission may not be doubled in the known electroluminescent element having two electroluminescent layers having the same thickness. Furthermore, the present inventors have found that, in the known electroluminescent element having a tandem structure, excess holes are generated in the electroluminescent layer formed closer to the anode electrode layer, which may be the reason why the current efficiency of the electroluminescent element is not doubled.

The present inventors have introduced a new design concept of achieving a carrier balance between a plurality of electroluminescent layers and solving the problem of imbalance in the amount of carrier supply by changing the configuration (thickness) of each electroluminescent layer itself as in the disclosure, into the electroluminescent element having a tandem structure including a plurality of electroluminescent layers. This makes it possible to generate an appropriate amount and balance of excitons in each electroluminescent layer in the layering direction without generating excessive carriers in the known electroluminescent element having a tandem structure, in the disclosure. As a result, in the disclosure, an electroluminescent device having a tandem structure capable of reducing current consumption and drive voltage and improving luminous efficiency is realized.

Specifically, in the disclosure, the thickness of the electroluminescent layer formed on the anode electrode layer side is made smaller than that of the electroluminescent layer formed on the cathode electrode layer side, in response to the fact that the supply amount of electrons supplied from the charge generation layer is smaller than the supply amount of holes supplied from the charge generation layer, that is, the supply amount of electrons among the carriers supplied to the electroluminescent layer formed closer to the anode electrode layer is smaller. As a result, to the electroluminescent layer on the anode electrode layer side, holes corresponding to the thickness of the electroluminescent layer are supplied. Accordingly, in the electroluminescent layer on the anode electrode layer side, electron-hole pairs (excitons) are generated without generating excess holes that cannot be combined with electrons, and excitons are also generated in an amount substantially equal to the theoretical value in the electroluminescent layer on the cathode electrode layer side. Thus, any electroluminescent layer overlapping in the layering direction emits light with a luminance corresponding to the thickness thereof. In addition, the generation of excess holes can be prevented in any electroluminescent layer, and thus, the current consumption can be reduced, whereby the power consumption can also be reduced.

Note that in particular, in a case of a top emission type configuration in which the electroluminescent element extracts light from the cathode electrode layer side, when there is even a slight defect in the sealing layer formed on the cathode electrode layer, the cathode electrode layer may deteriorate due to the penetration of oxygen or moisture, the electron injection property may decrease, and as a result, the amount of electrons supplied to the electroluminescent layer immediately below the cathode electrode layer may decrease. However, assuming such a case, the thickness of the electroluminescent layer on the cathode electrode layer side is formed to be smaller than the theoretical thickness from the initial design stage, whereby the generation of excess holes in the electroluminescent layer on the cathode electrode layer side can be prevented. From such a viewpoint, in the disclosure, the thickness of the electroluminescent layer on the cathode electrode layer side may be made smaller than the theoretical thickness within a range in which the effect of the disclosure is obtained.

Here, evaluation of a full color electroluminescent device including two electroluminescent layers (tandem structure) by simulation of Example and Comparative Example in the disclosure will be described. The conditions of the electroluminescent device were as follows: the thickness of the electroluminescent layer on the cathode electrode layer side was 35 nm for the red electroluminescent element and the green electroluminescent element, and 15 nm for the blue electroluminescent element; and the thickness of the electroluminescent layer on the anode electrode layer side was 7 nm for the red and green electroluminescent elements, and 3 nm for the blue electroluminescent element.

The electroluminescent device of Example has the layer configuration of the present embodiment. The ratio of the thickness of the anode electrode layer-side electroluminescent layer to the thickness of the cathode electrode layer-side electroluminescent layer is 1/5 for each of the red electroluminescent layer, the green electroluminescent layer, and the blue electroluminescent layer. The thickness of each stack of each color is 92 nm to 224 nm which is in a range of 80 nm or more and 250 nm or less, and the ratio of the thickness of the electroluminescent layer in each stack to the thickness of the stack is in a range of 0.03 or more and 0.75 or less. The electroluminescent device of Comparative Example is a full color electroluminescent device (not having a tandem structure) in which each layer has the same thickness as that of each layer of the stack on the cathode electrode layer side, and each color has a single electroluminescent layer.

According to the results of the simulation under the above conditions, the current efficiency (also referred to as “luminous efficiency”) of the full color electroluminescent device of the above Example was 1.2 times, the element lifetime was 1.3 times, and the drive voltage was 1.2 times those of the full color electroluminescent device of the above Comparative Example, respectively. From this result, it is found that the electroluminescent element of the above Example achieves an improvement in luminous efficiency commensurate with the increase in the drive voltage. Accordingly, it is found that, according to the electroluminescent device having the tandem structure of the disclosure, it is possible to suppress an increase in the drive voltage, extend the element lifetime, and improve the luminous efficiency commensurate with the increase in the drive voltage, as compared with the known full color electroluminescent device having the tandem structure.

Further, when the drive voltage was further increased to further improve the current efficiency (luminous efficiency) under the conditions in the simulation of the above Example, the current efficiency became 2 times at a drive voltage of 2 times, and in addition, the element lifetime under the conditions became 2.2 times. That is, it is found that the full color electroluminescent device having two electroluminescent layers (tandem structure) according to the disclosure can realize characteristics about 2 times those of the single-layer full color electroluminescent device.

In addition, when comparison was made between Example and Comparative Example described above for the blue electroluminescent element, the current efficiency of the electroluminescent device in the above Example is increased by 6.2%, the element lifetime is increased by 8.5%, and the drive voltage is decreased by 5.9%, relative to those of the electroluminescent device in the above Comparative Example, respectively. As is clear from the results, it is found that the electroluminescent device of the present embodiment can achieve a significant improvement in characteristics. In addition, according to the electroluminescent device of the present embodiment, there is also exhibited an effect that the amount of the guest compound (dopant) used can be reduced as compared with the known electroluminescent device having a tandem structure including a plurality of electroluminescent layers with the same thickness.

### Second Embodiment

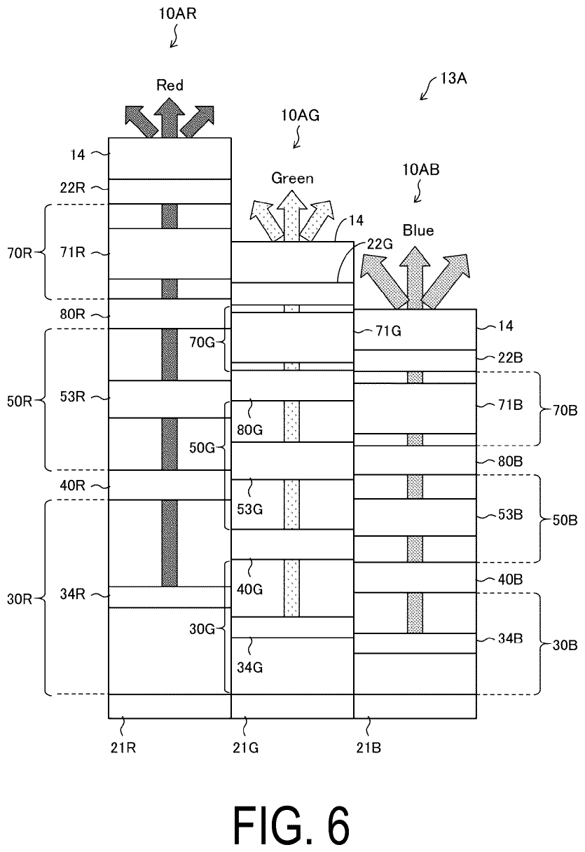

A second embodiment of the disclosure will be described below with reference to FIG. 6. FIG. 6 is a diagram for explaining a light emission mechanism of an electroluminescent element 10A of an electroluminescent device 13A according to the second embodiment of the disclosure. The electroluminescent device 13A according to the second embodiment is different from the electroluminescent device 13 described above in that the electroluminescent device 13A includes the electroluminescent element 10A having three electroluminescent layers in the layering direction.

Note that in FIG. 6, only the configuration of a main part of the electroluminescent element 10A included in the electroluminescent device 13A is illustrated. Note that, in the following description of the embodiment, for convenience of description, the same description as the description in the above-described embodiment is not repeated, and members having the same function as the members described in the above-described embodiment are denoted by the same reference signs, and descriptions therefor are not repeated.

As illustrated in FIG. 6, in a red electroluminescent element 10AR, a third electroluminescent layer 71R and a second charge generation layer 80R are further disposed between the cathode electrode layer 22R and the second electroluminescent layer 53R. In the red electroluminescent element 10AR, the layer set 50R including the second electroluminescent layer 53R disposed between the first charge generation layer 40R and the second charge generation layer 80R in the layering direction is the second stack. A layer set 70R including the third electroluminescent layer 71R disposed between the second charge generation layer 80R and the cathode electrode layer 22R is a third stack.

Similarly, in a green electroluminescent element 10AG, a third electroluminescent layer 71G and a second charge generation layer 80G are further disposed between the cathode electrode layer 22G and the second electroluminescent layer 53G. In the green electroluminescent element 10AG as well, the layer set 50G including the second electroluminescent layer 53G disposed between the first charge generation layer 40G and the second charge generation layer 80G in the layering direction is the second stack. A layer set 70G including the third electroluminescent layer 71G disposed between the second charge generation layer 80G and the cathode electrode layer 22G is the third stack.

In addition, in a blue electroluminescent element 10AB, a third electroluminescent layer 71B and a second charge generation layer 80B are further disposed between the cathode electrode layer 22B and the second electroluminescent layer 53B. In the blue electroluminescent element 10AB as well, the layer set 50B including the second electroluminescent layer 53B disposed between the first charge generation layer 40B and the second charge generation layer 80B in the layering direction is the second stack. A layer set 70B including the third electroluminescent layer 71B disposed between the second charge generation layer 80B and the cathode electrode layer 22B is the third stack.

Note that in the layer sets 30R, 30G, and 30B, the layer sets 50R, 50G, and 50B, and the layer sets 70R, 70G, and 70B included in the electroluminescent elements 10AR, 10AG, and 10AB of the respective colors, carrier function layers (such as an electron injection layer, an electron transport layer, a hole transport layer, and a hole injection layer) not illustrated are disposed. In the following description, the third electroluminescent layers 71R, 71G, and 71B included in the electroluminescent elements 10AR, 10AG, and 10AB of the respective colors are collectively referred to as “third electroluminescent layer 71”.

In the layering direction, when the thickness of the second electroluminescent layer 53 is 1, the thickness of the third electroluminescent layer 71 is 4 and the thickness of the first electroluminescent layer 34 is 1/4, for example. In this manner, the ratio of the thickness of the electroluminescent layer on the anode electrode layer side to the electroluminescent layer on the cathode electrode layer side is larger than 1/15 and smaller than 4/15. The thickness of each stack of each color is in a range of 80 nm or more and 250 nm or less, and the ratio of the thickness of the electroluminescent layer in each stack to the thickness of the stack is in a range of 0.03 or more and 0.75 or less. In the above range, the thicknesses of the electroluminescent layers 34, 53, and 71 included in the electroluminescent element 10A are larger on the cathode electrode layer 22 side and smaller on the anode electrode layer 21 side.

In FIG. 6 as well, the cathode electrode layer 22 may be a common layer provided across the red electroluminescent element 10AR, the green electroluminescent element 10AG, and the blue electroluminescent element 10AB. Similarly, the sealing layer 14 may be also a common layer provided across the red electroluminescent element 10AR, the green electroluminescent element 10AG, and the blue electroluminescent element 10AB.

Even in a case where there are three electroluminescent layers in the layering direction as illustrated in FIG. 6, supply of carriers (electrons or holes) which become excessive is prevented in an electroluminescent layer closer to the anode electrode layer, and all the electroluminescent layers emit light with luminance and luminous efficiency substantially according to theoretical values, similarly to the display device 100 illustrated in FIG. 5.

### Third Embodiment

The present embodiment is the same as the second embodiment described above except that only the thicknesses of two electroluminescent layers adjacent to each other in the layering direction among the three electroluminescent layers in the second embodiment described above have the specific ratio described above. Such an embodiment may be illustrated, for example, by a diagram modified in such a manner that the thicknesses of the electroluminescent layer 34 and the electroluminescent layer 53 in FIG. 6 are made the same, and the thickness of the electroluminescent layer 71 is greater than that of the electroluminescent layer 53.

As described above, in a case where the carrier balance is adjusted by a method other than the control of the thickness of the electroluminescent layer in the disclosure in two stacks adjacent to each other among the three stacks, and as a result, a good carrier balance is not obtained in the remaining one stack, the present embodiment is suitable for adjusting the carrier balance in the remaining one stack. Examples of such a configuration of the electroluminescent device include a configuration in which the ratio of the thicknesses of the electroluminescent layers between the second stack and the third stack is the above-described ratio of the thicknesses of the electroluminescent layers described in the disclosure in an electroluminescent device including one or more configurations selected from the group consisting of a configuration in which in the first stack and the second stack, the thicknesses of the corresponding carrier function layers are different, a configuration in which in the first stack and the second stack, the materials of the corresponding carrier function layers are different, and a configuration in which the material of the first electroluminescent layer included in the first stack and the material of the second electroluminescent layer included in the second stack are different.

In the present embodiment, the same effect as that of the first embodiment is exhibited in two electroluminescent layers adjacent to each other in the layering direction in the second embodiment.

### Main Actions and Effects

In the electroluminescent device of the disclosure, the plurality of electroluminescent layers are formed to overlap in the layering direction for each luminescent color, and in at least one set of sets of the electroluminescent layers, each of the sets being two electroluminescent layers adjacent to each other in the layering direction, the ratio of the thickness of the electroluminescent layer on the anode electrode layer side in the layering direction to the thickness of the electroluminescent layer on the cathode electrode layer side in the layering direction is larger than 1/15 and smaller than 4/15. With such a configuration, even in a case where the amount of electrons supplied from the charge generation layer is small, the carrier balance in the electroluminescent layer on the anode electrode layer side can be made uniform, and excess holes in the electroluminescent layer on the anode electrode layer side can be reduced. This makes it possible to greatly enhance the effect of reducing current consumption and greatly enhance the effect of improving luminous efficiency.

In addition, in the electroluminescent device of the disclosure, the thickness of the electroluminescent layer on the anode electrode layer side is smaller than the thickness of the electroluminescent layer on the cathode electrode layer side, and thus, the total thickness of the electroluminescent layers from the anode electrode layer to the cathode electrode layer is reduced by the reduction in thickness of the electroluminescent layer closer to the anode electrode layer, as compared with a case where the thickness of each electroluminescent layer in the layering direction is same. Accordingly, in a case where the electrical fields (unit: V/m) applied to the electroluminescent layers in the layering direction are the same, the drive voltage (unit: V) can be reduced. Furthermore, the generation of excess carriers in each of the electroluminescent layers can be suppressed, which reduces current consumption. Thus, a reduction in power consumption (unit: W=V×A) is also realized. Note that when the thicknesses of the electroluminescent layers are gradually reduced from the cathode electrode layer side toward the anode electrode layer side, further reduction in power consumption can be realized.

Accordingly, the electroluminescent device of the disclosure achieves higher luminance light emission, lower voltage driving, and lower power consumption than in the case of the known electroluminescent device having a tandem structure in which the electroluminescent layers have the same thickness in the layering direction. Thus, according to the disclosure, in an electroluminescent device capable of full color display without using a color filter or the like, it is possible to realize light emission with high luminance and/or power consumption saving, which is an advantage of the tandem structure.

In addition, when a host/guest system electroluminescent layer is used as the electroluminescent layer, high luminous efficiency and improvement in element lifetime can be realized, and according to the disclosure, the carrier balance (balance between electrons and holes) in each electroluminescent layer can be further enhanced. Accordingly, it is advantageous from the viewpoint that the performance of each of the host/guest system electroluminescent layers having high luminous efficiency and excellent lifetime can be sufficiently brought out. It is also advantageous in that the amount of an expensive and rare phosphorescent dopant to be used as a guest compound can be reduced.

In addition, in a case where the electroluminescent layer includes a fluorescent electroluminescent layer including a fluorescent dopant and a phosphorescent electroluminescent layer including a phosphorescent dopant, the number of fluorescent electroluminescent layers in the layering direction may be greater than the number of phosphorescent electroluminescent layers, for example, may be larger by 1 or 2. This configuration is more effective from the viewpoint of optimizing both the balance of the lifetime and the balance of the amount of light emission between the fluorescent electroluminescent layer and the phosphorescent electroluminescent layer.

Further, when the plurality of electroluminescent layers layered in the layering direction are made to have only the same color, it is advantageous from the viewpoint of realizing improvement in color purity in an electroluminescent device that enables full color display by separately forming the pixels of RGB. Furthermore, in a case where the same material emitting light of the same color is layered on each electroluminescent layer, the evaluation of the carrier injection property and the carrier transport property between the electroluminescent layers by simulation is more facilitated. As described above, the above configuration is still more effective from the viewpoint of more easily realizing an electroluminescent device capable of full color display including an electroluminescent element having desired characteristics.

In addition, when the ratio of the thickness of the electroluminescent layer in a stack to the thickness of the stack is set to 0.03 or more and 0.75 or less, the thickness of the carrier function layer is optimized, and the possibility of shortage of the amount of carriers supplied to the electroluminescent layer can be further reduced. Thus, it is more effective from the viewpoint of realizing light emission at the luminance of the theoretical value.

The electroluminescent device of the disclosure may be of a top emission type. This configuration is still more effective from the viewpoint of optimizing the thickness of the carrier function layer.

The charge generation layer may include an electron generation layer composed of an organic electron supply material. As described above, the electroluminescent device of the disclosure can solve the problem caused by the imbalance in the supply amounts of the carriers by setting the thickness of each electroluminescent layer in the layering direction. Thus, the disclosure is even more effective in a case where a charge generation layer in which the amount of electrons generated tends to be smaller than the amount of holes generated is used as the charge generation layer in the electroluminescent device. Further, the charge generation layer includes an organic electron supply material, and thus, it is not necessary to increase the vapor deposition temperature during formation of the electroluminescent element. This can reduce deterioration of the organic material included in other layers.

The number of electroluminescent layers disposed in the layering direction may be 2. The electroluminescent device of the disclosure is suitable for solving the problem caused by the imbalance in the supply amounts of carriers as described above with a smaller number of layers because the difference in thickness of the electroluminescent layers in the layering direction is relatively large. This configuration is also even more effective from the viewpoint of reducing the material and manufacturing costs of the electroluminescent layer.

A display device according to the disclosure includes the electroluminescent device described above. This allows the ratio of the thickness of the electroluminescent layer on the anode electrode layer side in the layering direction to the thickness of the electroluminescent layer on the cathode electrode layer side in the layering direction to be larger than 1/15 and smaller than 4/15. Accordingly, it is advantageous from the viewpoint that, in each electroluminescent layer in the layering direction, the current injected can be made to contribute to light emission without waste by preventing generation of excess carriers. Thus, according to the disclosure, light emission with high luminance and low power consumption is realized in the display device, and it is possible to sufficiently exhibit the advantages of adopting the tandem structure in the electroluminescent device.

In the electroluminescent device of the disclosure, forming at least the electroluminescent layer by a vapor deposition method is advantageous in realizing an electroluminescent device capable of full color display, because it is possible to form a host/guest system electroluminescent layer and to separately apply a light emitting layer with high resolution, as compared with a case where the electroluminescent layer is formed by other methods. In addition, it is also advantageous to realize control of the thickness of each electroluminescent layer with high accuracy. In particular, in formation of the electroluminescent layer by a coating method using an inkjet apparatus or the like, it is difficult to form the electroluminescent layer while doping a host compound with a guest compound and to control the thickness of the electroluminescent layer on the order of several nm. Accordingly, it is considered that it is difficult to form the electroluminescent device capable of full color display of the disclosure by the coating method.

In manufacturing of the electroluminescent device of the disclosure, the electroluminescent layers having different thicknesses in the layering direction may be formed by changing only the vapor deposition time. According to this configuration, the electroluminescent layers having different thicknesses can be formed in the same manufacturing facility by applying the same conditions except for the time, and thus, it is still more effective from the viewpoint of suppressing the manufacturing cost and improving the productivity.

Note that in an electroluminescent device including an electroluminescent element having a plurality of electroluminescent layers (tandem structure), the thicknesses of the electroluminescent layers in the layering direction are usually same. On the other hand, there are also a technique in which thicknesses of electroluminescent layers in the layering direction are different (JP 2007-329054 A, WO 2010/113493, JP 2015-153587 A, JP 2015-32582 A, and the like), and among them, there is a technique of including a thicker electroluminescent layer on the cathode electrode layer side and a thinner electroluminescent layer on the anode electrode layer side (JP 2007-329054 A, WO 2010/113493, and the like). However, in these known techniques, the reason why the thicknesses of electroluminescent layers are made different in the layering direction is not clarified, and the above publication does not disclose that the respective colors of RGB are separately applied to realize full color display.

According to the disclosure, in a display device using electroluminescence, it is possible to realize higher luminous efficiency, higher luminance, and/or lower power consumption by controlling the thicknesses of electroluminescent layers in the layering direction. Thus, the electroluminescent device and the display device of the disclosure are expected to contribute to achievement of, for example, Target 9.4 of Sustainable Development Goals (SDGs) advocated by the United Nations “upgrade infrastructure and retrofit industries to make them sustainable, with increased resource-use efficiency and greater adoption of clean and environmentally sound technologies and industrial processes”.

The disclosure is not limited to the embodiments described above, and various modifications may be implemented within a range not departing from the scope of the claims. Embodiments obtained by appropriately combining technical approaches disclosed in each of the different embodiments also fall within the scope of the technology of the disclosure. Furthermore, novel technical features can be formed by combining the technical approaches disclosed in the embodiments.

1. An electroluminescent device comprising:
an anode electrode layer;
a cathode electrode layer facing the anode electrode layer in a layering direction;
a plurality of electroluminescent layers disposed between the anode electrode layer and the cathode electrode layer in the layering direction and in a direction intersecting the layering direction; and
a charge generation layer disposed between two of the plurality of electroluminescent layers adjacent to each other in the layering direction,
wherein, of the plurality of electroluminescent layers,
the plurality of electroluminescent layers that emit light of a same color are disposed in the layering direction,
a first color electroluminescent layer to an n-th color electroluminescent layer (n is an integer of 2 or more) that emit light of colors different from each other are disposed in the direction intersecting the layering direction, and
in at least one set of sets of the electroluminescent layers, each of the sets being two of the plurality of electroluminescent layers adjacent to each other in the layering direction with the charge generation layer interposed therebetween, a ratio of a thickness of the electroluminescent layer on an anode electrode layer side in the layering direction to a thickness of the electroluminescent layer on a cathode electrode layer side in the layering direction is larger than 1/15 and smaller than 4/15.

2. The electroluminescent device according to claim 1,
wherein each of the plurality of electroluminescent layers is a host/guest system electroluminescent layer including a host compound and a guest compound.

3. The electroluminescent device according to claim 2,
wherein the plurality of electroluminescent layers include a fluorescent electroluminescent layer in each of which the guest compound is a fluorescent dopant and a phosphorescent electroluminescent layer in each of which the guest compound is a phosphorescent dopant, depending on a luminescent color, and
the number of the fluorescent electroluminescent layers in the layering direction is greater than the number of the phosphorescent electroluminescent layers in the layering direction.

4. The electroluminescent device according to claim 3,
wherein the number of the fluorescent electroluminescent layers in the layering direction is greater than the number of the phosphorescent electroluminescent layers in the layering direction by one or two.

5. The electroluminescent device according to any one of claims 1 to 4,
wherein only the plurality of electroluminescent layers that emit light of the same color are disposed in the layering direction.

6. The electroluminescent device according to any one of claims 1 to 5,
wherein when a layer set including one of the plurality of electroluminescent layers disposed between the anode electrode layer and the charge generation layer, between the charge generation layers, and between the charge generation layer and the cathode electrode layer in the layering direction is defined as a stack,
a ratio of a thickness of the electroluminescent layer in the stack to a thickness of the stack in the layering direction is 0.03 or more and 0.75 or less.

7. The electroluminescent device according to any one of claims 1 to 6, being a top emission type.

8. The electroluminescent device according to any one of claims 1 to 7,
wherein the charge generation layer includes an electron generation layer formed of an organic electron supply material.

9. The electroluminescent device according to any one of claims 1 to 8,
wherein the number of the plurality of electroluminescent layers disposed in the layering direction is 2.

10. A display device comprising:
the electroluminescent device according to any one of claims 1 to 9.

11. A method for manufacturing the electroluminescent device according to any one of claims 1 to 9, the method comprising:
alternately forming each of the plurality of electroluminescent layers and the charge generation layer on the anode electrode layer or the cathode electrode layer in the layering direction,
wherein the plurality of electroluminescent layers are formed by a vapor deposition method.

12. The method for manufacturing the electroluminescent device according to claim 11,
wherein the plurality of electroluminescent layers having different thicknesses in the layering direction are formed by changing only a vapor deposition time.
